(19) United States
(12) Patent Application Publication
(10) Pub. No.: US 2008/0246142 A1
(43) Pub. Date: Oct. 9, 2008

(54) Heat dissipation unit and a semiconductor package that has the heat dissipation unit

(75) Inventors: Jeng-Yuan Lai, Taichung Hsien (TW); Chien-Ping Huang, Taichung (TW); Chih-Ming Huang, Hsinchu Hsein (TW); Yu-Po Wang, Taichung (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/080,798

(22) Filed: Apr. 4, 2008

(30) Foreign Application Priority Data
Apr. 4, 2007 (TW) 096111968

(51) Int. Cl. H01L 23/367

(52) U.S. Cl. 257/712; 257/E23.101

(57) ABSTRACT

A heat dissipation unit and a semiconductor package having the same are disclosed. The semiconductor package includes a carrier; an electronic component mounted on and electrically connected to the carrier; a heat dissipation unit, which includes a flat section attached to the electronic component, extension sections connected to the flat section, and a heat dissipation section connected to the extension sections; and an encapsulant encapsulating the electronic component and the heat dissipation unit, wherein stress releasing sections are at least disposed at intersectional corners between the extension sections and the flat section so as to prevent projections from being formed by concentrated stresses in a punching process of the heat dissipation unit, thereby maintaining flatness of the flat section and further preventing circuits of the electronic component from being damaged due to a contact point produced between the electronic component and the flat section in a molding process.

### BACKGROUND OF THE INVENTION

1. Field of the Invention

This invention generally relates to a semiconductor package technique, and more specifically to a heat dissipation unit and a semiconductor package having the same.

2. Description of Related Art

Since semiconductor chips generate a large amount of heat during operation, in the fabrication process of a semiconductor package of nowadays, a heat spreader or a heat dissipation structure is usually mounted to a semiconductor chip of the package to enhance heat dissipation efficiency.

In U.S. Pat. No. 6,444,498, the fabrication method of a semiconductor package includes providing a chip carrier that carries a plurality of chips arranged in an array; then mounting a heat spreader of large area on upper surfaces of the chips; thereafter, performing an encapsulation molding process and a singulation process, and removing the encapsulant on the upper surface of the heat spreader. However, owing to cutting of the heat spreader involved in the abovementioned singulation process and removal of the encapsulant remaining on the upper surface of the heat spreader, the fabrication process is complicated and the fabrication cost is increased. A heat dissipation technique applicable to a semiconductor package is disclosed by U.S. Pat. No. 6,236,568, wherein a chip is electrically connected to a substrate by means of wire bonding, and a heat spreader is correspondingly mounted in a space above the chip and exposed from the encapsulant for dissipating heat generated by the chip during operation. In order to efficiently transmit heat to the heat spreader located in the space above the chip, the chip is connected to the heat spreader via a heat transmission element in a manner that the bottom surface of the heat transmission element is disposed on the central area of the chip to avoid the wire bonding area and the top surface of the heat transmission element being attached to the heat spreader. Thus, heat generated by the chip can be rapidly transmitted to the heat spreader and further dissipated to the outside. However, stress is usually concentrated on the central area of the chip in the molding process, so as to damage the chip.

According to U.S. Pat. Nos. 6,541,310 and 6,933,175, instead of using the heat transmission element as that in the U.S. Pat. No. 6,236,568, an encapsulant is filled between the heat spreader and the chip so as to avoid the above-described chip damage caused by stress concentrated on the central area of the chip in the molding process. However, the encapsulant filled between the heat spreader and the chip results in a high thermal resistance, such that even though the upper surface of the heat spreader is exposed from the encapsulant, heat cannot be dissipated instantly, thus resulting in a poor heat dissipation efficiency.

FIG. 1A shows a semiconductor package 1 disclosed by U.S. Pat. No. 5,616,957. The semiconductor package 1 includes a die pad 10, a lead frame 11, a chip 12 mounted on the die pad 10 and connected to the lead frame 11 by wire bonding, a heat dissipation unit 13 adhered to the central area of the chip 12, and an encapsulant 14 that encapsulates all the aforementioned elements. The heat dissipation unit 13 further includes a flat section 130 adhered to the central area of the chip 12, extension sections 131 extending from sides of the flat section 130, and heat dissipation sections 132 extending horizontally outward from the extension sections 131. The heat dissipation unit 13 is wholly embedded inside the encapsulant 14. Although the heat dissipation unit 13 is not exposed from the encapsulant 14 as those in U.S. Pat. Nos. 6,541,310, 6,933,175, 6,236,568, and 6,444,498, the heat dissipation area is increased due to the widely extended heat dissipation sections 132, thereby improving the heat dissipation efficiency.

Compared with U.S. Pat. Nos. 6,541,310 and 6,933,175 that fill space between the chip and the heat spreader with an encapsulant of high thermal resistance, the heat dissipation unit 13 that is disclosed in U.S. Pat. No. 5,616,957 is directly mounted on the chip 12. Thus, heat generated by the chip during operation can be dissipated directly.

However, referring to FIGS. 1B and 1C, since the heat dissipation unit is fabricated by means of punching, projections can be easily formed at intersection corners of the flat section 120 and adjacent extension sections 131 due to material squeeze and unreleased stress. Accordingly, the flat section 130 becomes uneven. When the heat dissipation unit 13 is adhered to the chip 12, the projections form contact points with the chip 12, and in the subsequent molding process, stresses will concentrate on the contact points and further damage the circuits on the chip 12.

Hence, it is a highly urgent issue in the industry to provide a technique which can effectively solve the drawbacks of the prior art as mentioned above.

### SUMMARY OF THE INVENTION

In view of the disadvantages of the prior art, it is an objective of the present invention to provide a heat dissipation unit and a semiconductor package having the same that have a simplified fabrication process and a low cost.

It is another objective of the present invention to provide a heat dissipation unit and a semiconductor package having the same that prevent chip damage.

It is a further objective of the present invention to provide a heat dissipation unit and a semiconductor package having the same that prevent circuits on the chip of the semiconductor package from being damaged by projections of the heat dissipation unit due to concentrated stresses.

It is still another objective of the present invention to provide a heat dissipation unit and a semiconductor package having the same that rapidly dissipate heat generated by the chip during operation.

To achieve the aforementioned and other objectives, the present invention provides a heat dissipation unit for dissipating heat generated by an electronic component of a semiconductor package. The heat dissipation unit includes a flat section attached to a top of the electronic component; extension sections connected to sides of the flat section and extending away from the electronic component; a heat dissipation section connected to the extension section and extending outwardly away from a center of the electronic component; and stress releasing sections at least disposed at intersectional corners between the flat section and the extension sections.

The present invention further provides a semiconductor package having the heat dissipation unit, which includes a carrier; an electronic component mounted on and electrically connected to the carrier; a heat dissipation unit, which includes a flat section attached to a top of the electronic component, extension sections connected to the flat section and extending away from the electronic component, and a heat dissipation section connected to the extension sections and extending outwardly away from a center of the electronic component, wherein stress releasing sections are at least disposed at intersectional corners between the flat section and the extension sections; and an encapsulant formed on the carrier for encapsulating the electronic component and the heat dissipation unit

The heat dissipation unit may be fabricated by means of punching. The stress releasing sections can be holes formed at the intersectional corners between the flat section and the extension sections or strip-shaped grooves disposed along intersectional lines between the extension sections and extending to the intersectional corners, thereby preventing projections from being formed on the heat dissipation unit in the punching process so as to keep the flatness of the flat section.

Compared with the prior art wherein projections are formed on a heat dissipation unit during a punching process so as to form contact points with a chip, thus causing damage to circuit on the chip during a molding process by stress concentrated on the contact points, the present invention can keep flatness of the flat section by disposing stress releasing sections, thus avoiding damage to circuits on a chip caused by stress concentrated on contact points in a subsequent molding process.

The carrier of the semiconductor package can be a substrate or a lead frame, the electronic component can be a chip that generates a large amount of heat during operation, and the chip can be electrically connected to the carrier by means of wire bonding or flip chip.

In addition, the heat dissipation unit of semiconductor package according to the present invention is directly attached to the electronic component without the need of a heat transmission element as in the prior art, thereby reducing the fabrication cost.

Furthermore, compared with the prior art that fills an encapuslant between a heat spreader and a chip and consequently leads to poor heat dissipation efficiency, the heat dissipation unit according to the present invention is directly attached to the electronic component. Thus, heat generated by the electronic component during operation can be dissipated efficiently.

### BRIEF DESCRIPTION OF DRAWINGS

The present invention can be more fully understood by reading the following detailed description of the preferred embodiments, with reference made to the accompanying drawings, wherein:

FIG. 1A is a diagram showing a sectional view of a semiconductor package of the prior art;

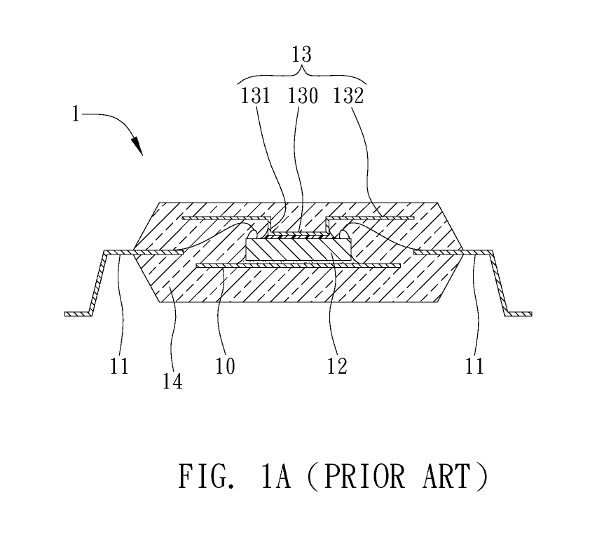

FIG. 1B is a diagram showing a conventional heat dissipation unit with projections;

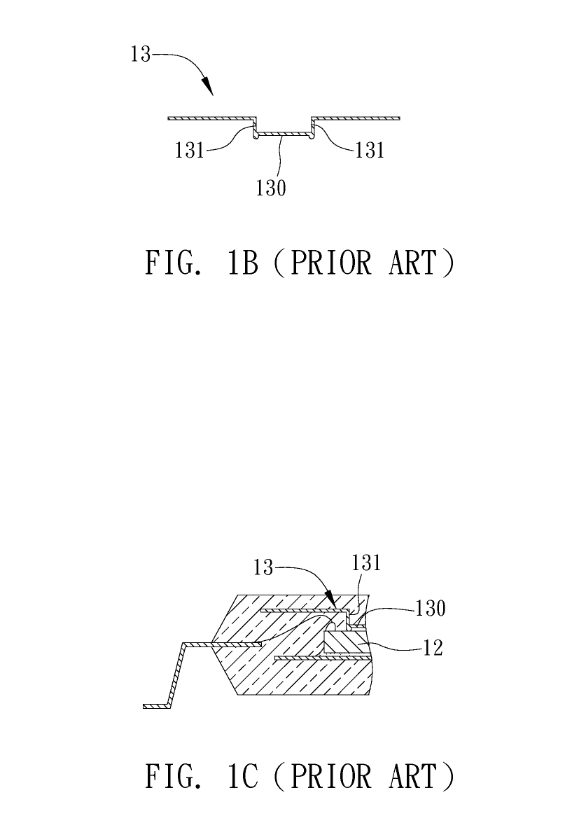

FIG. 1C is a diagram showing a partial sectional view of a conventional semiconductor package with a heat dissipation unit having projections;

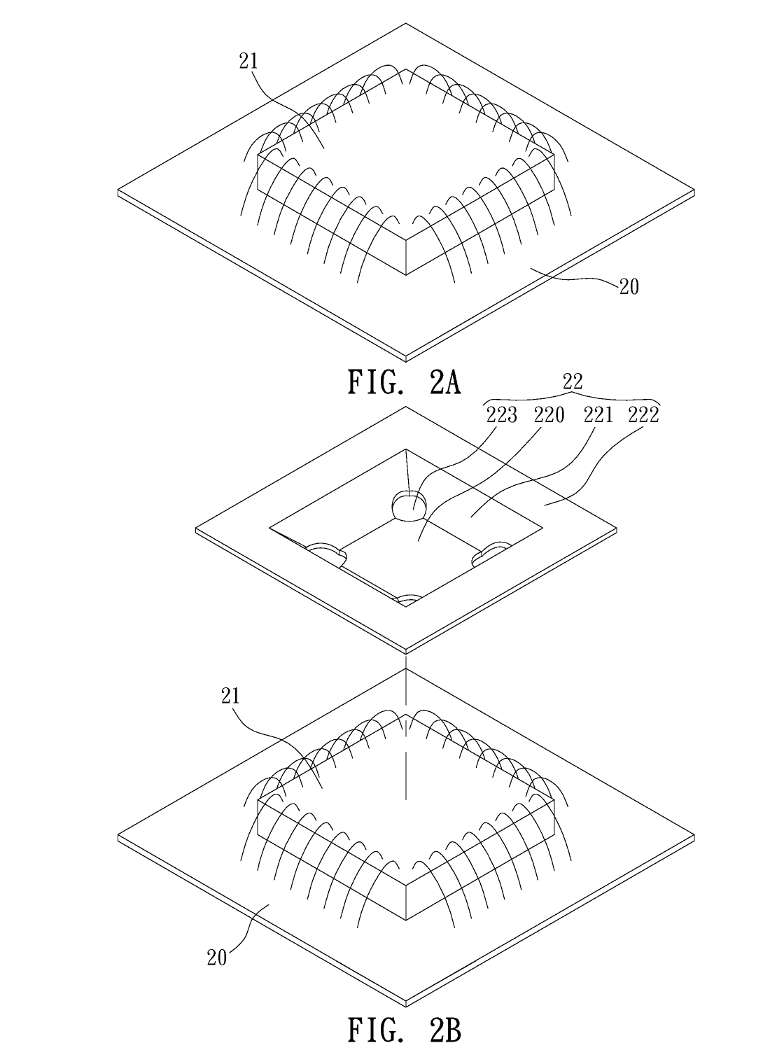

FIGS. 2A through 2D are diagrams showing a heat dissipation unit and a semiconductor package having the same according to the first embodiment of the present invention; and

FIGS. 3A and 3B are block diagrams showing a heat dissipation unit according to the second embodiment of the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

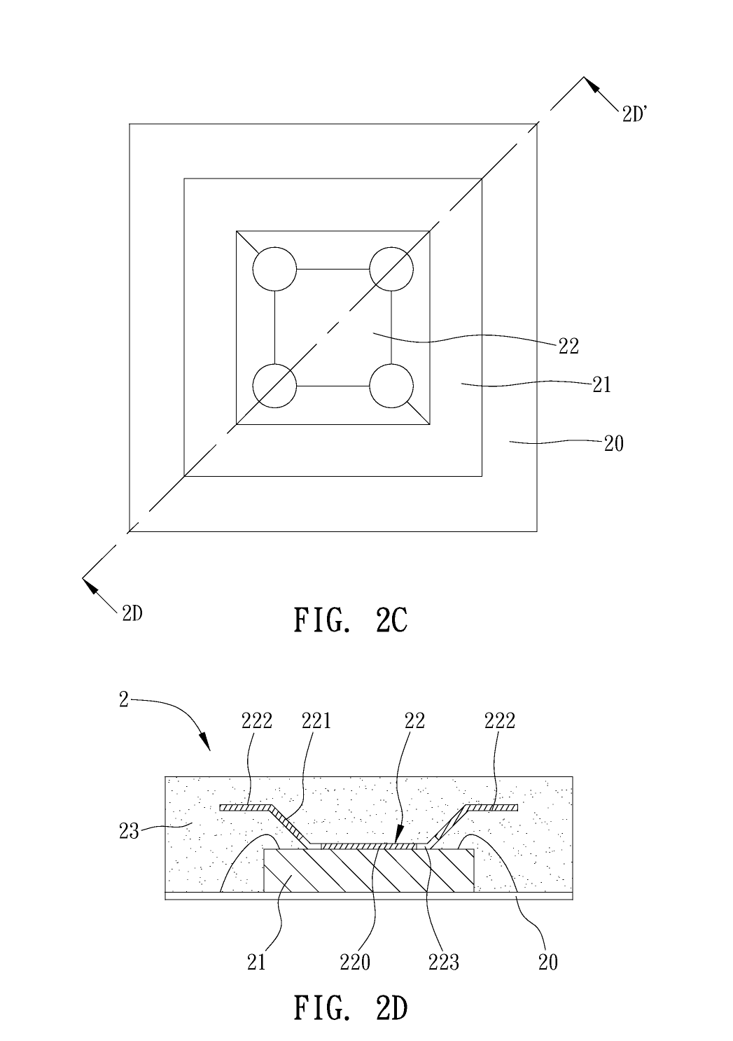

Please refer to FIGS. 2A through 2D, which illustrate a heat dissipation unit and a semiconductor package having the same according to the first embodiment of the present invention.

As shown in FIG. 2A, an electronic component 21 is mounted on and electrically connected to a carrier 20 so as to form a semi-fabricated package, wherein the carrier 20 can be a substrate or a lead frame, and the electronic component 21 is a chip that generates a large amount of heat while operating. The electronic component 21 is electrically connected to the carrier 20 by bonding wires.

Referring to FIG. 2B, a heat dissipation unit 22 is disposed at a central area of the electronic component 21. The heat dissipation unit 22 includes a flat section 220 attached to the top of the electronic component 21, extension sections 221 connected to sides of the flat section 220 and extending away from the electronic component 21, and a heat dissipation section 222 connected to the extension sections 221 and extending outwardly away from the center of the electronic component 21, wherein stress releasing sections 223 are disposed at intersectional corners between the flat section 220 and the extension sections 221.

The stress releasing sections 223 are such as round holes, square holes, or holes of other shapes, which release squeeze stress accumulated on material of the heat dissipation unit 22 in a subsequent punching process.

The extension sections 221 are vertically connected to the flat section 220 or connected at an oblique angle with respect to the flat section 220. Generally, in order to obtain a broader heat dissipation area and heat conducting path, it is preferred that the extension sections 221 are connected at an oblique angle with respect with the flat section 220.

The heat dissipation section 222 extends parallel to the carrier 20 so as to minimize thickness of the finished semiconductor package and meanwhile obtain a preferred heat dissipation effect due to the long extension distance.

The stress releasing sections 223 can prevent projections from being formed on the heat dissipation unit 22 during a punching process so as to keep flatness of the flat section 220. Thus, the flat section 220 can be evenly attached to the electronic component 21 so as to efficiently dissipate heat generated by the electronic component 21 during operation.

Please refer to FIG. 2C, which is a top view diagram of the aforementioned heat dissipation unit 22 attached to the top of the electronic component 21, and FIG. 2D shows a sectional view of the structure in FIG. 2C along a line 2D-2D′. Therein, an integrated structure of the heat dissipation unit 22, the electronic component 21 and the carrier 20 is disposed into an encapsulation mold (not shown) such that an encapsulation molding process can be performed to form an encapsulant 23 encapsulating the electronic component 21 and the heat dissipation unit 22, thereby obtaining a semiconductor package 2.

Since the stress releasing sections 223 such as holes are formed in the heat dissipation unit 22 of the present invention, no projection is formed on the heat dissipation unit 22 during the punching process, thereby keeping the flatness of the flat section 220. As a result, no projecting contact point is formed between the flat section 220 and the electronic component 21, and stresses can be evenly distributed without damaging circuits of the electronic component 21 in a subsequent molding process.

It should be noted hereby that the electronic component 21 of the present embodiment is a chip that is electrically connected to the carrier 20 by means of wire bonding. Alternatively, the electronic component 21 can be a chip that is electrically connected to the carrier 20 by means of flip chip.

### Second Embodiment

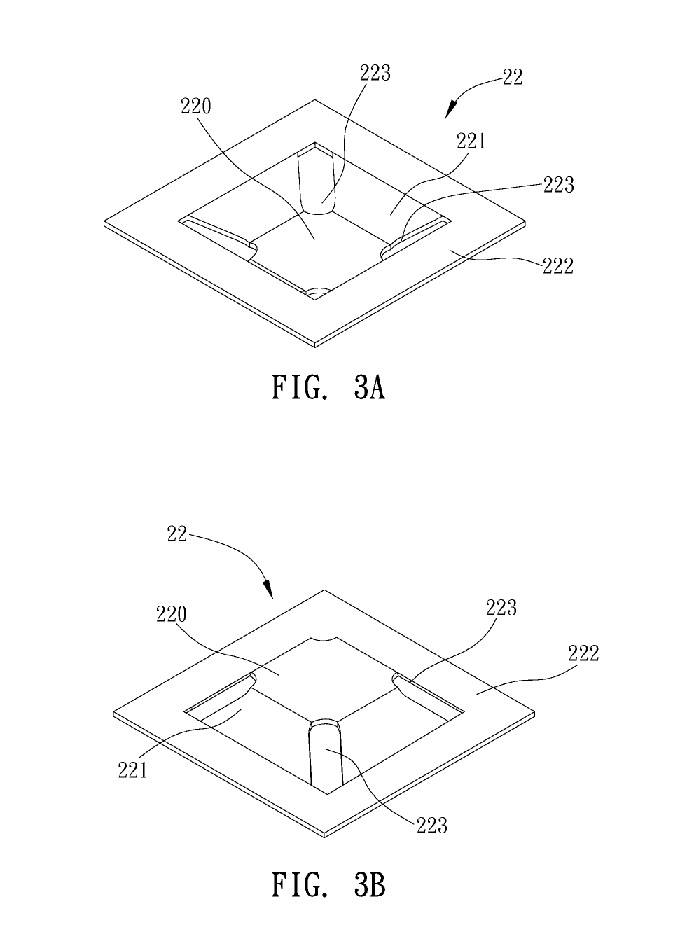

Please refer to FIGS. 3A and 3B, which are block diagrams illustrating a heat dissipation unit according to the second embodiment of the present invention. The present embodiment is similar to the first embodiment. The difference therebetween is the stress releasing sections 223 of the present embodiment are strip-shaped grooves formed along intersectional lines between any two adjacent extension sections 221 and extending to the intersectional corners to prevent the intersectional lines from being deformed due to stress concentrated on the intersectional lines and further keep flatness of the flat section 220 of the heat dissipation unit 22.

Compared with the prior art that has a heat transmission element disposed between a chip and a heat spreader and consequently has high fabrication cost and even has a risk of chip damage during a molding process, the heat dissipation unit 22 of the semiconductor package 2 according to the present invention is directly attached to the electronic component 21. Thus, not only the fabrication cost is lower but also chip damage is prevented from occurring during the molding process.

Furthermore, compared with the disadvantage of poor heat dissipation efficiency of the heat dissipation unit of the prior art that fills space between a heat spreader and a chip with an encapsulant, the heat dissipation unit 22 of the semiconductor package 2 according to the present invention is directly attached to the electronic component 21, which accordingly provides a preferred heat dissipation efficiency.

However, the foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A semiconductor package, comprising:
a carrier;
an electronic component mounted on and electrically connected to the carrier;
a heat dissipation unit comprising a flat section attached to a top of the electronic component, extension sections connected to sides of the flat section and extending away from the electronic component, and a heat dissipation section connected to the extension sections and extending outwardly away from a center of the electronic component, wherein a plurality of stress releasing sections are at least disposed at intersectional corners between the flat section and the extension sections; and
an encapsulant formed on the carrier and encapsulating the electronic component and the heat dissipation unit.

2. The semiconductor package of claim 1, wherein the plurality of stress releasing sections are holes formed at the intersectional corners between the extension sections and the flat section.

3. The semiconductor package of claim 2, wherein the holes are round holes.

4. The semiconductor package of claim 1, wherein the stress releasing sections are strip-shaped grooves disposed along intersectional lines of any two adjacent extension sections and extending to intersectional corners.

5. The semiconductor package of claim 1, wherein the extension sections are vertically connected to the flat section.

6. The semiconductor package of claim 1, wherein the extension sections are connected at an oblique angle with respect to the flat section.

7. The semiconductor package of claim 1, wherein the carrier is one of a substrate and a lead frame, and the electronic component is a chip.

8. The semiconductor package of claim 7, wherein the chip is electrically connected to the carrier by one of wire bonding and flip chip.

9. The semiconductor package of claim 1, wherein the heat dissipation section of the heat dissipation unit extends parallel to the carrier.

10. A heat dissipation unit for dissipating heat generated by an electronic component of a semiconductor package during operation, comprising:
a flat section attached to a top of the electronic component;
extension sections connected to sides of the flat section and extending away from the electronic component;
a heat dissipation section connected to the extension sections and extending outwardly from a center of the electronic component; and
a plurality of stress releasing sections at least disposed at intersectional corners between the flat section and the extension sections.

11. The heat dissipation unit of claim 10, wherein the stress releasing sections are holes formed at the intersectional corners between the extension sections and the flat section.

12. The heat dissipation unit of claim 11, wherein the holes are round holes.

13. The heat dissipation unit of claim 10, wherein the stress releasing sections are strip-shaped grooves disposed along intersectional lines of any two adjacent extension sections and extending to intersectional corners.

14. The heat dissipation unit of claim 10, wherein the extension sections are vertically connected to the flat section.

15. The heat dissipation unit of claim 10, wherein the extension sections are connected at an oblique angle with respect to the flat section.
